(19) United States
(12) Patent Application Publication
(10) Pub. No.: US 2006/0269694 A1
(43) Pub. Date: Nov. 30, 2006

(54) Plasma processing method

(75) Inventors: Minoru Honda, Amagasaki-shi (JP); Toshio Nakanishi, Amagasaki-shi (JP)

Correspondence Address: C. IRVIN MCCLELLAND;OBLON, SPIVAK, MCCLELLAND, MAIER & NEUSTADT, P.C., 1940 DUKE STREET, ALEXANDRIA, VA, 22314, US

(73) Assignee: TOKYO ELECTRON LIMITED, Minato-Ku (JP)

(21) Appl. No.: 11/442,272

(22) Filed: May 30, 2006

(30) Foreign Application Priority Data
May 30, 2005 (JP) 2005-157841

(51) Int. Cl. H05H 1/24; G06F 19/00; B29C 71/04; B05C 11/00; C23C 16/00

(52) U.S. Cl. 427/569; 427/532; 118/723 R; 118/697; 700/123; 118/723 MW

(57) ABSTRACT

A plasma processing method for forming a silicon nitride film is provided. A nitrogen-containing plasma is used to nitride silicon on a surface of a target object in a processing chamber of a plasma processing apparatus. The plasma processing method includes a first step of performing a plasma processing under a condition wherein a nitriding reaction is mediated mainly through radical species of the nitrogen-containing plasma, and a second step of performing a plasma processing under a condition wherein the nitriding reaction is mediated mainly through ion species of the nitrogen-containing plasma.

### FIELD OF THE INVENTION

The present invention relates to a plasma processing method for processing a target object such as a semiconductor substrate by using a plasma to nitride silicon of a surface of the substrate to form a silicon nitride film thereon.

### BACKGROUND OF THE INVENTION

In a manufacturing process of various kinds of semiconductor devices, a silicon nitride film is formed, e.g., as a gate insulating film of a transistor. Along with the recent progress in a miniaturization of the semiconductor devices, the gate insulating film also tends to be getting thinner. Therefore, it is required to form a thin silicon nitride film having a film thickness of several nanometers.

As a typical method for forming the silicon nitride film, a silicon oxide film, e.g., SiO₂, formed in advance, is used to be nitrided later. However, as a technology for directly nitriding single crystalline silicon by a plasma processing, there are disclosed a method for forming a silicon nitride film by introducing an NH₃ gas in a reaction chamber of a microwave plasma CVD apparatus at a process pressure of 100 Torr (13332 Pa) and at a process temperature of 1300 °C.; and a method for forming a silicon nitride film by introducing an N₂ gas in the reaction chamber at a process pressure of 50 mTorr (6.7 Pa) and at a process temperature of 1150 °C. in, for example, Patent Document 1 (Japanese Patent Laid-open Application No. H9-227296 (see paragraphs [0021], [0022] and the like)).

However, as described in Patent Document 1, if the silicon is directly nitrided, a film quality is likely to be deteriorated. For example, reduction of N concentration (N desorption) is expected to occur as time passes, so that a stable silicon nitride film cannot be obtained.

### SUMMARY OF THE INVENTION

It is, therefore, an object of the present invention to provide a technology capable of forming a nitride film having a good quality, in which silicon is directly nitrided by using a plasma.

In accordance with a first aspect of the present invention, there is provided a plasma processing method for forming a silicon nitride film, wherein a nitrogen-containing plasma is used to directly nitride silicon on a surface of a target object in a processing chamber of a plasma processing apparatus, the plasma processing method including: a first step of performing a plasma processing under a condition wherein a nitriding reaction is mediated mainly through radical species of the nitrogen-containing plasma; and a second step of performing a plasma processing under a condition wherein the nitriding reaction is mediated mainly through ion species of the nitrogen-containing plasma.

Further, in accordance with a second aspect of the present invention, there is provided a plasma processing method for forming a silicon nitride film, wherein a nitrogen-containing plasma is used to nitride silicon on a surface of a target object in a processing chamber of a plasma processing apparatus, the plasma processing method including: a first step of performing a plasma processing at a process pressure of 133.3 Pa˜1333 Pa; and a second step of performing a plasma processing at a process pressure of 1.33 Pa˜26.66 Pa.

In the first and second aspect of the present invention, it is preferred that the nitrogen-containing plasma is formed by introducing a microwave into the processing chamber with a planar antenna having a plurality of slots. In this case, it is preferred that an electron temperature of the nitrogen-containing plasma is 0.7 eV or less in the first step; and the electron temperature of the nitrogen-containing plasma is 1.0 eV or greater in the second step. Further, it is preferred that the plasma processing by the second step is performed after performing the plasma processing by the first step until the silicon nitride film is grown to a film thickness of about 1.5 nm.

In accordance with a third aspect of the present invention, there is provided a computer executable control program for controlling, when executed, the plasma processing apparatus, so that the plasma processing method of the first or second aspect is performed.

In accordance with a fourth aspect of the present invention, there is provided a computer storage medium for storing a computer executable control program, wherein the control program controls, when executed, the plasma processing apparatus so that the plasma processing method of the first or second aspect is performed.

In accordance with a fifth aspect of the present invention, there is provided a plasma processing apparatus including: a plasma source for generating a plasma; a vacuum chamber for processing a target object by the plasma; a substrate supporting table for mounting thereon the target object in the chamber; and a controller for allowing the plasma processing method of the first or second aspect to be performed.

Further, in accordance with a sixth aspect of the present invention, there is provided a plasma processing method for forming a nitride film or an oxide film, wherein a nitrogen-containing plasma or an oxygen-containing plasma is used to nitride or oxidize a surface of a target object in a processing chamber of a plasma processing apparatus, the plasma processing method including: a first step of performing a plasma processing under a condition wherein a nitriding reaction or an oxidation reaction is mainly mediated through radical species of the nitrogen-containing plasma or the oxygen-containing plasma, respectively; and a second step of performing a plasma processing under a condition wherein the nitriding reaction or an oxidation reaction is mainly mediated through ion species of the nitrogen-containing plasma or the oxygen-containing plasma, respectively. In this case, it is preferred that the nitrogen-containing plasma or the oxygen-containing plasma is formed by introducing a microwave into the processing chamber with a planar antenna having a plurality of slots.

Further, in accordance with a seventh aspect of the present invention, there is provided a plasma processing method for forming a nitride film or an oxide film, wherein a nitrogen-containing plasma or an oxygen-containing plasma is used to nitride or oxidize a surface of a target object in a processing chamber of the plasma processing apparatus, the plasma processing method including: a first step of performing a plasma processing at a process pressure equal to or greater than 66.65 Pa and equal to or less than 1333 Pa; and a second step of performing the plasma processing at a process pressure equal to or greater than 1.33 Pa and less than 66.65 Pa.

In accordance with the present invention, the film can be formed by N radical base in the first half stage of a nitride film growth, and the film can be formed by N ion base having a reactivity in the second half stage of a nitride film formation, by performing a first step of performing a plasma processing under a condition (for example, a processing pressure of 133.3 Pa˜1333 Pa) wherein a nitriding reaction is mediated mainly through radical species of the nitrogen-containing plasma; and a second step of performing a plasma processing under a condition (for example, a processing pressure of 1.33 Pa˜26.66 Pa) wherein the nitriding reaction is mediated mainly through ion species of the nitrogen-containing plasma.

Therefore, a silicon nitride film of a desired film thickness and a good quality can be formed efficiently. In accordance with the silicon nitride film obtained by the method of the present invention, because an N desorption hardly occurs although the film thickness is 1.5 nm or thicker, and a high N concentration can be maintained, the method of the present invention is useful to form a gate insulating film or the like of a film thickness of about, e.g., 2 nm in a manufacturing process of semiconductor devices progressing towards miniaturization.

By forming the nitrogen-containing plasma by introducing the microwave into the processing chamber with the planar antenna having a plurality of slots so that the electron temperature of the plasma and an ion energy are further reduced, a plasma damage can be further reduced.

### BRIEF DESCRIPTION OF THE DRAWINGS

The above and other objects and features of the present invention will become apparent from the following description of preferred embodiment given in conjunction with the accompanying drawings, in which:

FIG. 1 offers a schematic cross-sectional view showing an example of a plasma processing apparatus which can be used in accordance with the present invention;

FIG. 2 shows a view provided for explaining a planar antenna;

FIG. 3 is a flow chart showing a sequence of plasma nitriding process;

FIGS. 4A to 4C depict exemplary views showing cross sections of a wafer for explaining a process of forming a gate electrode;

FIG. 5 is a graph showing relations between an N concentration in a film and a film thickness after the film being left untreated for 1.5 hours, obtained by an XPS analysis;

FIG. 6 offers a view showing a profile expected to be obtained by performing a two-step process;

FIG. 7 is a graph showing an electron temperature of a plasma in case a pressure is changed;

FIG. 8 is a graph showing a relation between the N concentration in a film and the film thickness obtained by the XPS analysis; and

FIG. 9 is a graph showing relations between a variation of the N concentration in a film and the film thickness after the film being left untreated for 3 to 24 hours, obtained by the XPS analysis.

### DETAILED DESCRIPTION OF THE PREFERRED EMBODIMENTS

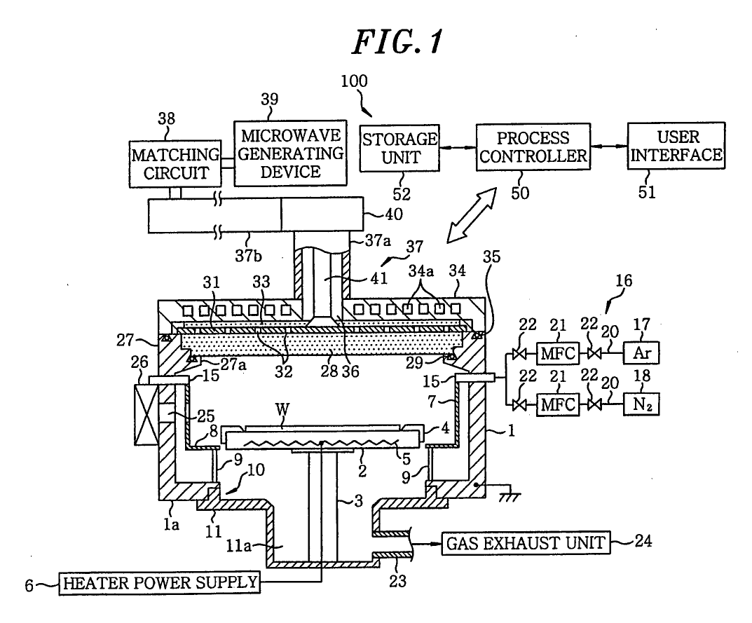

Hereinafter, a preferred embodiment of the present invention will be specifically described with reference to the accompanying drawings. FIG. 1 is a cross-sectional view exemplarily showing an example of a plasma processing apparatus that can be suitably used in accordance with the present invention. By introducing a microwave into a processing chamber by using a planar antenna having a plurality of slots, particularly an RLSA (Radial Line Slot Antenna), to generate a plasma, the plasma processing apparatus 100 is configured as an RLSA microwave plasma processing apparatus capable of generating a microwave plasma of a high density and a low electron temperature. Further, in a manufacturing process of various semiconductor devices, e.g., a MOS transistor, a MOSFET (field-effect transistor) and the like, it can be suitably used, e.g., to form a gate insulating film.

The plasma processing apparatus 100 includes a substantially cylindrical chamber 1 which is airtight and grounded. A circular opening 10 is formed at a substantially central portion of a bottom surface la of the chamber 1, and the bottom surface 1a is provided with an exhaust chamber 11 communicating with the opening 10 and protruding downward.

A susceptor 2 serving as a mounting table and made of a ceramic, e.g., AlN or the like, is provided in the chamber 1 to horizontally support a silicon wafer (hereinafter referred to as a “wafer”) W. The susceptor 2 is supported by a cylindrical supporting member 3 made of the ceramic, e.g., AlN or the like, and extending upwardly from a central bottom portion of the exhaust chamber 11. A guide ring 4 for guiding the wafer W is provided on an outer periphery portion of the susceptor 2. Further, a resistance heater 5 is buried in the susceptor 2 to heat the susceptor 2 by a power supplied from a heater power supply 6. The wafer W serving as a target object is heated by thus generated heat. At this time, the temperature of the wafer W can be controlled in a range, e.g., from the room temperature to 800 °C. Further, on an inner periphery of the chamber 1, a cylindrical liner 7 made of quartz is provided to prevent metal contamination caused by constituent materials of the chamber. Accordingly, an inside of the chamber is maintained in a clean environment. Further, at a periphery of the susceptor 2, a ring shaped baffle plate 8 for uniformly exhausting the chamber 1 is provided, wherein the baffle plate 8 is supported by a plurality of support columns.

The susceptor 2 is provided with wafer supporting pins (not shown) for supporting the wafer W to lift up and down the same so that the wafer supporting pins can be protruded from a surface of the susceptor 2 and lowered thereinto.

A ring shaped gas introducing member 15 is provided on a sidewall of the chamber 1, and a gas supply system 16 is connected to the gas introducing member 15. The gas introducing member 15 is provided with a plurality of gas inlet openings, uniformly formed so that the gas can be uniformly introduced into the chamber 1. Further, the gas introducing member 15 may be disposed in the form of a nozzle shape or a shower shape. The gas supply system 16 includes, for example, an Ar gas supply source 17, an N₂ gas supply source 18, and these gases are supplied to the gas introducing member 15 through their respective gas lines 20, and then introduced into the chamber 1 from the gas introducing member 15. Each of the gas lines 20 is provided with a mass flow controller 21 and opening/closing valves 22 disposed at an upstream and a downstream of the mass flow controller 21. Further, instead of the N₂ gas, for example, an NH₃ gas, a gaseous mixture of N₂ and H₂, or the like can be used. Further, instead of the Ar gas, a rare gas such as Kr, Xe, He, Ne, or the like can be used.

A gas exhaust line 23 is connected on a side surface of the exhaust chamber 11, and a gas exhaust unit 24 including a high speed vacuum pump is connected to the gas exhaust line 23. By operating the gas exhaust unit 24, a gas in the chamber 1 is uniformly discharged into a space 11a of the exhaust chamber 11 via the baffle plate 8, thereby being exhausted through the gas exhaust line 23. Accordingly, the inside of the chamber 1 can be depressurized to a predetermined vacuum level, e.g., 0.133 Pa, at a high speed.

On a sidewall of the chamber 1, a loading/unloading port 25 for transferring the wafer W between the chamber 10 and a transfer chamber (not shown) adjacent to the plasma processing apparatus 100 and a gate valve 26 for opening and closing the loading/unloading port 25 are provided.

An upper portion of the chamber 1 is formed as an opening, and a ring shaped upper plate 27 is connected to the opening. A lower portion of an inner periphery of the upper plate 27 is protruding into a space of the chamber, forming a ring shaped support portion 27a. A microwave transmitting plate 28 made of a dielectric material, e.g., the quartz, or the ceramic, e.g., Al₂O₃, AlN, or the like, is airtightly disposed on the support portion 27a through a sealing member 29. Therefore, the inside of the chamber 1 is airtightly maintained.

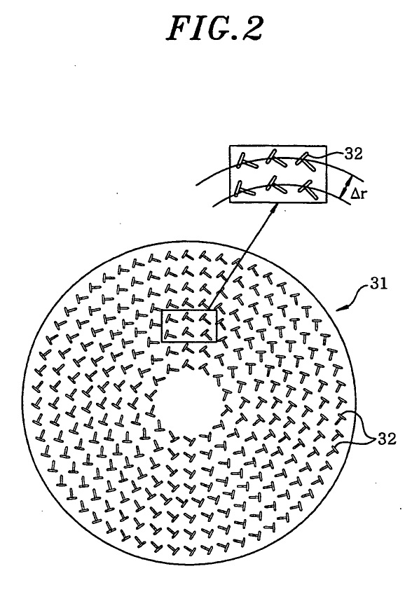

A circular plate shaped planar antenna 31 is provided on the microwave transmitting plate 28 to face the susceptor 2. The planar antenna 31 is hanging on a top portion of the sidewall of the chamber 1. The planar antenna 31 is made of, e.g., aluminum plate or copper plate plated with gold or silver, and is provided with a plurality of microwave radiation holes 32 formed therethrough in a predetermined pattern. The microwave radiation holes 32 are formed in, e.g., a long groove shape as shown in FIG. 2, and typically, the adjacent microwave radiation holes 32 are disposed in a T-shape, and the plurality of microwave radiation holes 32 are concentrically disposed. A length of the microwave radiation hole 32 or an arrangement interval therebetween is determined in accordance with a wavelength λg of the microwave, and the microwave radiation holes 32 are disposed so that the interval therebetween is λg/4, λg/2 or λg. Further, in FIG. 2, the interval between the adjacent microwave radiation holes 32 concentrically formed is shown as Δr. Further, the microwave radiation holes 32 may be formed in a different shape such as a circular shape, a circular arc shape or the like. Further, the arrangement of the microwave radiation holes 32 is not limited to a specific form and they can be disposed in a different shape, e.g., a spiral shape, a radial shape, other than a concentric circular shape.

On a top surface of the planar antenna 31, a wave retardation member 33 having a dielectric constant greater than that of a vacuum is provided. The wave retardation member 33 has a function to prevent the wavelength of the microwave from becoming longer in the vacuum and shorten the wavelength of the microwave to efficiently supply the microwave to the slots. Further, the planar antenna 31 and the microwave transmitting plate 28 may be in contact with or separated from each other and so may be the wave retardation member 33 and the planar antenna 31.

On a top surface of the chamber 1, a shield lid member 34 made of a metal material, e.g., an aluminum, a stainless steel or the like, is provided to cover the planar antenna 31 and the wave retardation member 33. The top surface of the chamber 1 and the shield lid member 34 are sealed together by a sealing member 35. A cooling water path 34a is formed in the shield lid member 34 so that the shield lid member 34, the wave retardation member 33, the planar antenna 31 and the microwave transmitting plate 28 can be cooled by flowing cooling water therethrough. Further, the shield lid member 34 is grounded.

The shield lid member 34 has an opening 36 in a center of its top wall, and a waveguide 37 is connected to the opening. A microwave generating device 39 is connected to an end portion of the waveguide 37 via a matching circuit 38. Accordingly, a microwave having a frequency of, e.g., 2.45 GHz generated from the microwave generating device 39 is propagated to the planar antenna 31 through the waveguide 37. A microwave having a frequency of 8.35 GHz, 1.98 GHz, or the like can be used.

The waveguide 37 includes a coaxial waveguide 37a having a circular cross section and extending upward from the opening 36 of the shield lid member 34, and a rectangular waveguide 37b extending in a horizontal direction and connected to an upper portion of the coaxial waveguide 37a via a mode converter 40. The mode converter 40 between the rectangular waveguide 37b and the coaxial waveguide 37a has a function to convert a TE mode of the microwave propagating in the rectangular waveguide 37b into a TEM mode. An inner conductor 41 is provided, extending at a center of the coaxial waveguide 37a, and a lower portion of the inner conductor 41 is fixedly connected to a center of the planar antenna 31. Accordingly, the microwave is efficiently and uniformly propagated to the planar antenna 31 through the inner conductor 41 of the coaxial waveguide 37a in a radial shape.

Each component of the plasma processing apparatus 100 is connected to a process controller 50 including a CPU to be controlled thereby. A user interface 51 including a keyboard by which a process administrator performs an input operation of a command and the like to control the plasma processing apparatus 100, a display for displaying an operation status of the plasma processing apparatus 100, or the like, is connected to the process controller 50.

Further, a storage unit 52 for storing a control program (software) which realizes various processes performed by the plasma processing apparatus 100 by a control of the process controller 50, or recipes, each recipe containing process condition data and the like recorded therein, is connected to the process controller 50.

Further, when necessary, by executing an arbitrary recipe loaded from the storage unit 52 in the process controller 50 by the command from the user interface 51 or the like, a desired process is performed in the plasma processing apparatus 100 under a control of the process controller 50. Further, it is possible to use the control program or the recipe containing the process condition data or the like, in a state stored in a computer readable storage medium, e.g., a CD-ROM, a hard disk, a flexible disk, a flash memory, or the like. Or, it can be used on-line by being transmitted from a different device, for example, via a dedicated line when necessary.

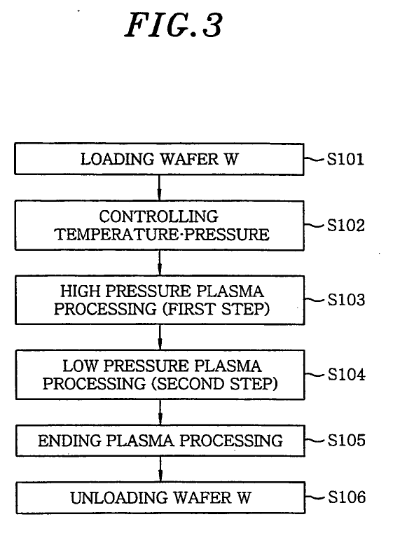

In the RLSA type plasma processing apparatus 100 configured as described above, a silicon layer (polycrystalline silicon or single crystalline silicon) of the wafer W can be directly nitrided so that a process for forming a silicon nitride film is performed. Hereinafter, a process sequence is described with reference to FIG. 3.

First of all, in step S101, the gate valve 26 is opened, and the wafer W having the silicon layer formed thereon is loaded into the chamber 1 through the loading/unloading port 25. And then, from the Ar gas supply source 17 and the N₂ gas supply source 18 of the gas supply system 16, the Ar gas and the N₂ gas are introduced into the chamber 1 through the gas introducing member 15 at predetermined flow rates, respectively. Specifically, first of all, for a first step, the flow rate of the rare gas such as Ar or the like and the flow rate of the N₂ gas are set to be 250˜5000 mL/min (sccm) and 50˜2000 mL/min (sccm), respectively. A process pressure in the chamber is controlled to be 66.65 Pa˜1333 Pa (0.5 Torr˜10 Torr), and preferably to be 133.3 Pa˜666.5 Pa (1 Torr˜5 Torr). Further, it is possible to use only the N₂ gas without using the rare gas.

Further, the wafer W is heated to a temperature of about 400˜800 °C., and preferably to a higher temperature of about 600˜800 °C. to achieve a synergy effect, in step S102.

Next, in step S103, the microwave generated from the microwave generating device 39 is guided to the waveguide 37 via the matching circuit 38 to be supplied to the planar antenna 31 via the rectangular waveguide 37b, the mode converter 40, the coaxial wave guide 37a, and the inner conductor 41 in that order. And then, the microwave is radiated through the slots of the planar antenna 31 into the chamber 1 via the microwave transmitting plate 28. The microwave propagates in the rectangular waveguide 37b in the TE mode, and the TE mode of the microwave is converted into the TEM mode in the mode converter 40 so that the microwave may be propagated through the coaxial waveguide 37a toward the planar antenna 31, and then, propagated outwardly in the radial direction of the planar antenna 31. An electromagnetic field is formed in the chamber 1 by the microwave radiated from the planar antenna 31 into the chamber 1 through the microwave transmitting plate 28 to plasmarize the Ar gas and the N₂ gas. The microwave is radiated through the plurality of microwave radiation holes 32 of the planar antenna 31 so that the microwave plasma having a high density of about 1×10¹˜5×10¹²/cm³ is formed. Further, the microwave plasma having a low electron temperature is formed near the wafer W. At that time, a microwave power can be 1500˜5000 W.

Plasma damage caused on an underlying film by ions or the like of thus formed microwave plasma is low, and plasma damage can be further reduced by conducting a high pressure process at a pressure equal to or greater than 66.65 Pa, preferably at a pressure equal to or greater than 133.3 Pa, in the first step such that a nitriding reaction is mainly mediated through radical species of the plasma. At that time, the electron temperature of the plasma is 0.7 eV or less, and is preferably 0.6 eV or less. N is directly introduced into the silicon by an action of active species, for example, mainly nitrogen radicals N* and the like, in the plasma so that the silicon nitride film having a good quality is formed.

After the silicon nitride film is grown to a predetermined film thickness, for example, 1.5 nm in the first step, the process pressure is reduced so that a nitriding process is performed in a second step (step S104). Specifically, the flow rate of the rare gas such as Ar or the like is set to be 250˜5000 mL/min (sccm), and the flow rate of the N₂ gas is set to be 10˜1000 mL/min (sccm), and preferably set to be 10˜100 mL/min (sccm). And the process pressure in the chamber is controlled to be 1.33 Pa˜66.65 Pa (10 mTorr˜500 mTorr), and preferably to be 6.7 Pa˜39.99 Pa (50 mTorr˜300 mTorr). The temperature of the wafer W may be the same as that in the first step. Further, in the preferred embodiment, the terms “high pressure” and “low pressure” have a purely relative meaning.

Then, as in the first step, the microwave generated from the microwave generating device 39 is introduced into the chamber 1 through the planar antenna 31 to plasmarize the Ar gas and the N₂ gas by thus formed electromagnetic field.

In the second step, a low pressure process is conducted at a pressure less than 66.65 Pa, preferably at a pressure equal to or less than 39.99 Pa, more preferably at a pressure equal to or less than 26.66 Pa, so that the. nitriding reaction mainly occurs by nitrogen ions in the plasma. Because the electron temperature of the plasma is greater than 0.7 eV, preferably 1 eV or greater, and more preferably 1.2 eV or greater in such a case, and thus, N can be introduced even in the film thicker than 1.5 nm by nitrogen ions with high energy, the nitriding reaction can be carried out continuously. In other words, N is directly introduced into the silicon by the action of active species, mainly nitrogen ions and the like, so that the silicon nitride film of a desired film thickness can be formed.

After the second step is ended, the plasma is stopped to be generated, processing gases are stopped to be introduced, and the chamber is exhausted to a vacuum so that the plasma nitriding process is ended (step S105). After that, the wafer W is unloaded (step S106), and then, another wafer W is processed, if necessary.

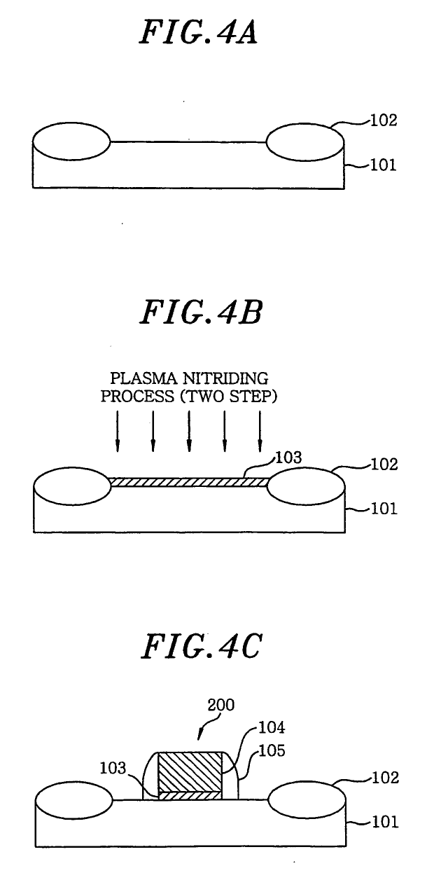

As described above, the silicon nitride film having a good quality can be formed on a surface of the single crystalline silicon or the polycrystalline silicon. Therefore, the process of the present invention can be suitably applied to, for example, a case of forming the silicon nitride film serving as the gate insulating film in a manufacturing process of various semiconductor devices, e.g., a transistor or the like. FIGS. 4A to 4C are views for explaining an example in which the plasma processing method of the present invention is applied to a manufacturing process of the transistor.

As shown in FIG. 4A, by using, for example, a LOCOS (Local Oxidation of Silicon) method, a device isolation region 102 is formed on a Si substrate 101 in which a well region (diffusion area: not shown) doped with P⁺ or N⁺ is formed, wherein the device isolation region 102 may be formed by an STI (Shallow Trench Isolation) method.

Subsequently, as shown in FIG. 4B, the plasma nitriding process, which is a two-step process, is performed as described above to form a gate insulating film 103 (Si₃N₄) on a surface of the Si substrate 101. Although a film thickness of the gate insulating film 103 is varied depending on a device to be fabricated, it can be about, for example, 1˜5 nm, preferably 1˜2 nm.

Then, after a polysilicon layer 104 is formed on thus formed gate insulating film 103 by, for example, a CVD process, a gate electrode is formed by etching the polysilicon layer 104 by using a photolithography technology. Further, a gate electrode structure is not limited to a single layer structure of the polysilicon layer 104, but may be a laminated structure including, e.g., tungsten, molybdenum, tantalum, titanium, a silicide thereof, a nitride, an alloy, or the like to improve a speed of the gate electrode by reducing a resistivity thereof. As shown in FIG. 4C, for thus formed gate electrode, a sidewall 105 of an insulating film is formed, and a source and a drain (not shown) are formed by performing an ion implantation and an activation process, to fabricate a transistor 200 having a MOS structure.

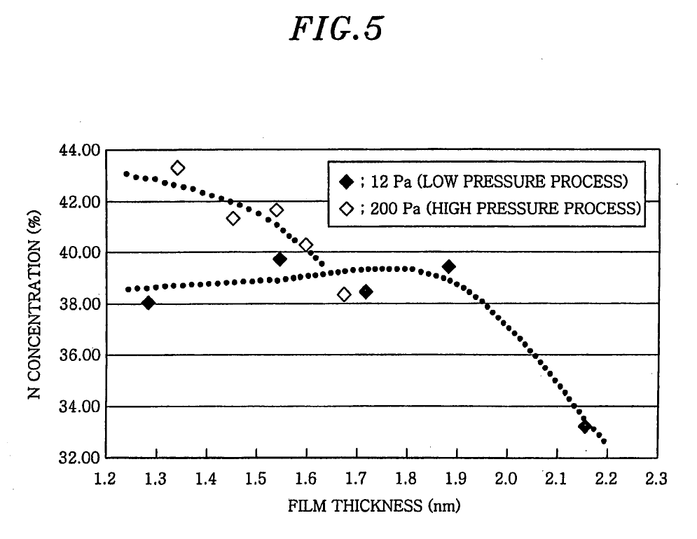

Hereinafter, an experimental data forming the basis of the present invention will be described with reference to FIG. 5. FIG. 5 is a graph plotting relations between an N concentration in the film and the film thickness, wherein the silicon substrates were left untreated for 1.5 hours after the silicon substrates had been directly nitrided under different pressures, respectively, to form their respective silicon nitride films by using the plasma processing apparatus 100 having the same configuration as the one shown in FIG. 1.

A plasma processing of this experiment was divided into a low pressure process and a high pressure process.

Low Pressure Process

The flow rates of Ar and N₂ serving as processing gases were 1000 mL/min (sccm) and 40 mL/min (sccm), respectively; the pressure was 12 Pa (90 mTorr); the temperature of the wafer was 800 °C.; and a power supplied to the plasma was 1.5 kw.

High Pressure Process

The flow rates of Ar and N₂ serving as processing gases were 1000 mL/min (sccm) and 200 mL/min (sccm), respectively; the pressure was 200 Pa (1500 mTorr); the temperature of the wafer was 800 °C.; and a power supplied to the plasma was 1.5 kw.

As shown in FIG. 5, in case of the high pressure process conducted at a pressure of 200 Pa, although the N concentration is high in the nitride film and the film quality is good to a nitride film thickness of about 1.5˜1.6 nm, the N concentration tends to sharply decrease at the nitride film thickness greater than 1.6 nm. Meanwhile, in case of the low pressure process conducted at a pressure of 12 Pa, although the N concentration is substantially constant to a nitride film thickness of about 2.0 nm, the N concentration tends to be generally low when compared to that of the high pressure process, and the N concentration tends to sharply decrease at the nitride film thickness greater than 2.0 nm.

In the high pressure process, because the electron temperature of the plasma is low and the nitriding reaction is mainly mediated through the radicals (N radicals) of the plasma, the film quality is good. However, because a reactivity of the radicals is low when compared to that of the ions (N ions), if the film thickness is thicker than 1.6 nm, it is difficult for the radicals to reach an interface of the silicon and the nitride film which is being formed, so that a thick nitride film cannot be formed. Meanwhile, in the low pressure process, because the nitriding reaction is mainly mediated through the ions (N ions) of the plasma, if the film thickness is about 2.0 nm or less, the ions can reach the interface of the silicon and the nitride film which is being formed, so that the nitriding reaction proceeds and the thick nitride film is formed.

From the result described above, it is found that the thick silicon nitride film having a good quality can be formed by employing the two-step process. In the two-step process, to the nitride film thickness of, e.g., 1.5 nm, the plasma processing is performed under a high pressure plasma condition with a low energy, wherein the nitriding reaction is mainly mediated through the radical species of the plasma so that the silicon is not damaged in a first stage of the nitriding process. After that, the plasma processing is performed under a low pressure plasma processing condition with a high energy, wherein the nitriding reaction is mainly mediated through the ion species of the plasma.

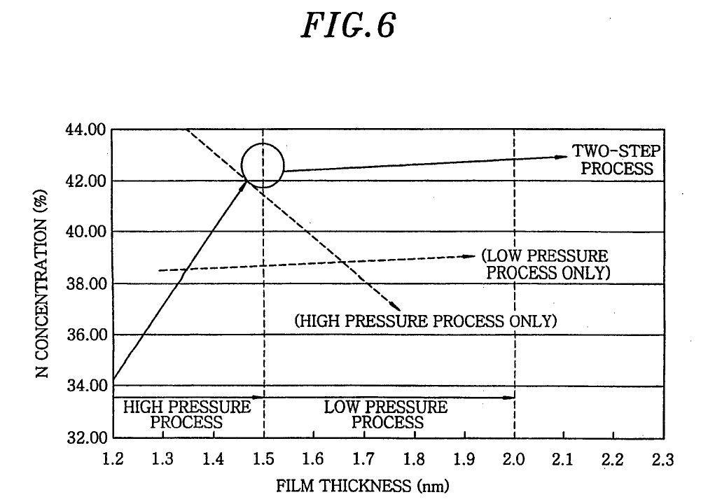

A principle of the two-step process is shown in FIG. 6. In the two-step process, the high pressure condition wherein the nitriding process is performed at a pressure of 66.65 Pa or greater mainly by the action of the radical species, and the low pressure condition wherein the nitriding process is performed at a pressure less than 66.65 Pa mainly by the action of the ion species, are combined. And, as shown in FIG. 6, the nitride film is grown to a predetermined film thickness, e.g., to the film thickness of about 1.5 nm, under the high pressure plasma processing condition in the first stage. Subsequently, at a transition point determined by the film thickness of the first stage (marked by an open circle in the drawing), the condition is changed to the low pressure plasma condition therefrom while the nitride film is growing. Accordingly, the film can be nitrided to a film thickness of, e.g., 2.0 nm by using the merits of the high pressure condition and the low pressure condition.

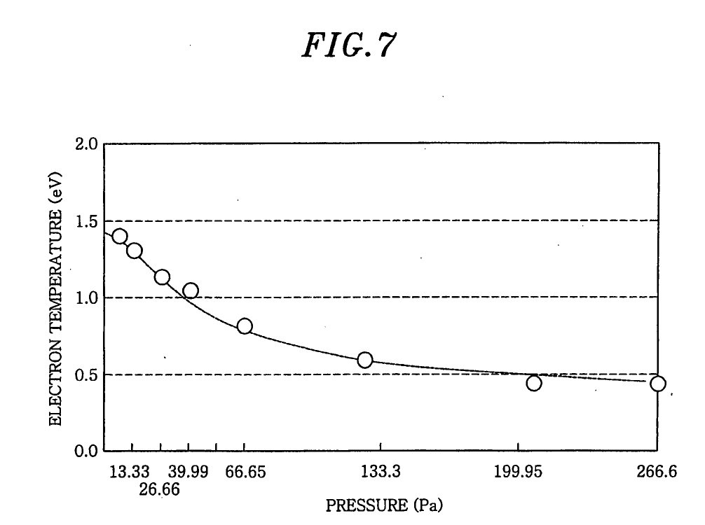

FIG. 7 shows a variation of the electron temperature of the plasma in case the process pressure is changed in the plasma processing apparatus 100 shown in FIG. 1. Further, the flow rates of Ar and N₂ serving as processing gases were 1000 mL/min (sccm) and 200 mL/min (sccm), respectively; the temperature of the wafer was 800 °C.; and a power supplied to the plasma was 1.5 kW. In FIG. 7, it can be known that the electron temperature is reduced as the pressure increases; the electron temperature is reduced to a temperature of 0.7 eV or less in case the pressure is 66.65 Pa or greater; and the electron temperature is reduced to a temperature of 0.6 eV or less in case the pressure is 133.3 Pa or greater.

Meanwhile, referring to FIG. 7, it can be known that the electron temperature is generally high under a low pressure less than 66.65 Pa; the electron temperature is 1.0 eV or greater in case the pressure is 39.99 Pa or less; and the electron temperature is 1.2 eV or greater in case the pressure is 26.66 Pa or less. Therefore, the electron temperature of the plasma can be controlled by using the two-step process in which the pressure is changed.

Next, by using the plasma processing apparatus 100, the Si substrate was directly nitrided by employing the two-step process of the present invention in which the plasma processing under the high pressure condition and that under the low pressure condition were successively performed. After thus formed film was left untreated for 1.5 hours, the N concentration in the nitride film was measured by an X-ray photoelectron spectroscopy (XPS analysis).

The plasma conditions of the nitriding process are as follows:

First Step

The flow rates of Ar and N₂ serving as processing gases were 1000 mL/min (sccm) and 200 mL/min (sccm), respectively; the pressure was 200 Pa (1500 mTorr); the temperature of the wafer was 800 °C.; and the power supplied to the plasma was 1.5 kW.

Second Step

The flow rates of Ar and N₂ serving as processing gases were 1000 mL/min (sccm) and 40 mL/min (sccm), respectively; the pressure was 12 Pa (90 mTorr); and the rest was the same as in the first step.

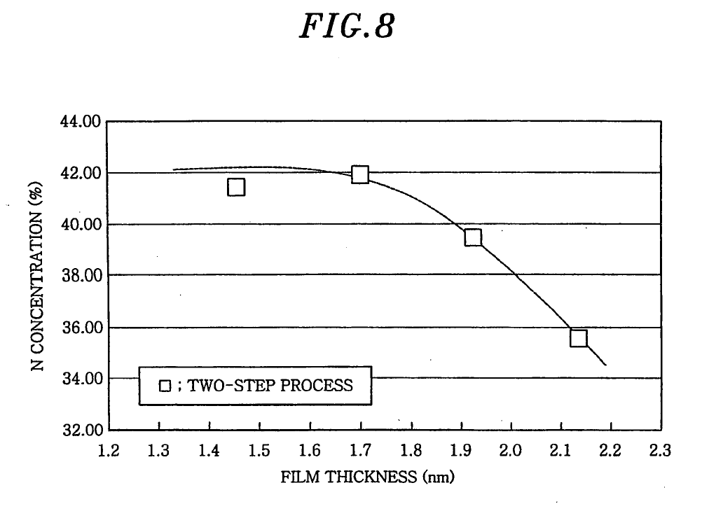

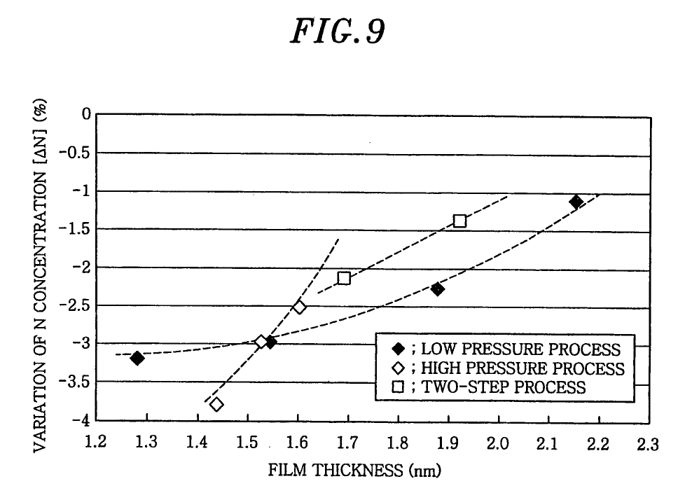

FIG. 8 provides results thereof. Further, the nitride films were formed by employing the two-step process, the low pressure process, and the high pressure process, respectively. FIG. 9 shows relations between a variation ΔN of the N concentration and the film thickness after the films were left untreated in the atmosphere for 3 to 24 hours.

Referring to FIG. 8, by the two-step process including the high and low pressure processes, the N concentration in the nitride film was high to a film thickness of about 2.0 nm, and thus, a nitride film having a good quality was formed. Further, referring to FIG. 9, in case the film thickness is about 1.5˜2.0 nm, it is shown that the variation of the N concentration (N desorption) is low after a Queue time of 3˜24 hours, and the nitride film having a good quality can be formed by the two-step process, when compared to a single pressure process conducted at a high or low pressure. On the other hand, in the nitriding of the single pressure process conducted at a high pressure (performed mainly by the radicals), it seems that the N desorption is increased as time passes because new Si-N forming reaction does not proceed sufficiently when the film thickness becomes thicker than 1.5 nm, and thus unbounded or free N species are increased in the nitride film. Further, in the nitriding of the single pressure process conducted at a low pressure (performed mainly by the ions), it seems that the N desorption is increased as time passes because the unbounded or free N species are increased in the film by breakage of the already formed Si-N bonds or the like, by high energy ions generated during the plasma processing.

From the results shown in FIGS. 8 and 9, it is found that, by performing the two-step process including the high and low pressure processes, when compared to the nitriding process including a single step for performing only a high pressure process or for performing only low pressure process, the N desorption is low, the film quality of the nitride film can be improved, and the nitride film can be formed to a desired film thickness. Specifically, because the silicon nitride film having a good film quality can be obtained in case the film thickness is about 2.0 nm, it is useful to form a thin film, e.g., a gate insulating film having a thickness of 5 nm or less (preferably about 1˜2 nm) or the like, in a next-generation device.

Although the preferred embodiment of the invention has been described, the present invention is not limited thereto, and various changes can be made.

For example, although FIG. 1 shows the RLSA type plasma processing apparatus 100 as an example, the present invention may be applied to a plasma processing apparatus of, for example, a remote plasma type, an ICP (Inductively Coupled Plasma) type, or an ECR (Electron Cyclotron Resonance) type.

Further, the plasma processing method of the present invention is not limited to forming the gate insulating film of the transistor, and can be applied to a formation of insulating films for other semiconductor devices, for example, to perform the nitriding process of a gate oxide film [for example, an SiO₂ film thermally oxidized by WVG (Wafer Vapor Generation), an SiO₂ film oxidized by a plasma, or the like] or the like. Further, it can be applied to the nitriding process of a high-k material, e.g., HfSiO, HfO₂, ZrSiO, ZrO₂, Al₂O₅, TaO₅ or the like, a capacitor material, or the like. Further, the two-step-plasma processing of the present invention is not limited to a formation of the nitride film, and can be applied to, e.g., a formation of an oxide film.

While the invention has been shown and described with respect to the preferred embodiment, it will be understood by those skilled in the art that various changes and modifications may be made without departing from the scope of the invention as defined in the following claims.

What is claimed is:

1. A plasma processing method for forming a silicon nitride film, wherein a nitrogen-containing plasma is used to nitride silicon on a surface of a target object in a processing chamber of a plasma processing apparatus, the plasma processing method comprising:
a first step of performing a plasma processing under a condition wherein a nitriding reaction is mediated mainly through radical species of the nitrogen-containing plasma; and
a second step of performing a plasma processing under a condition wherein the nitriding reaction is mediated mainly through ion species of the nitrogen-containing plasma.

2. The plasma processing method of claim 1, wherein the nitrogen-containing plasma is formed by introducing a microwave into the processing chamber with a planar antenna having a plurality of slots.

3. The plasma processing method of claim 1 or 2, wherein an electron temperature of the nitrogen-containing plasma is 0.7 eV or less in the first step; and the electron temperature of the nitrogen-containing plasma is 1.0 eV or greater in the second step.

4. The plasma processing method of claim 1, wherein the plasma processing by the second step is performed after performing the plasma processing by the first step until the silicon nitride film is grown to a film thickness of about 1.5 nm.

5. A plasma processing method for forming a silicon nitride film, wherein a nitrogen-containing plasma is used to nitride silicon on a surface of a target object in a processing chamber of a plasma processing apparatus, the plasma processing method comprising:
a first step of performing a plasma processing at a process pressure of 133.3 Pa˜1333 Pa; and
a second step of performing a plasma processing at a process pressure of 1.33 Pa˜26.66 Pa.

6. The plasma processing method of claim 5, wherein the nitrogen-containing plasma is formed by introducing a microwave into the processing chamber with a planar antenna having a plurality of slots.

7. The plasma processing method of claim 5, wherein an electron temperature of the nitrogen-containing plasma is 0.7 eV or less in the first step; and the electron temperature of the nitrogen-containing plasma is 1.0 eV or greater in the second step.

8. The plasma processing method of claim 5, wherein the plasma processing by the second step is performed after performing the plasma processing by the first step until the silicon nitride film is grown to a film thickness of about 1.5 nm.

9. A computer executable control program for controlling, when executed, the plasma processing apparatus, so that the plasma processing method of claim 1 or 5 is performed.

10. A computer storage medium for storing a computer executable control program, wherein the control program controls, when executed, the plasma processing apparatus so that the plasma processing method of claim 1 or 5 is performed.

11. A plasma processing apparatus comprising:
a plasma source for generating a plasma;
a vacuum chamber for processing a target object by the plasma;
a substrate supporting table for mounting thereon the target object in the chamber; and
a controller for allowing the plasma processing method of claim 1 or 5 to be performed.

12. A plasma processing method for forming a nitride film or an oxide film, wherein a nitrogen-containing plasma or an oxygen-containing plasma is used to nitride or oxidize a surface of a target object in a processing chamber of a plasma processing apparatus, the plasma processing method comprising:
a first step of performing a plasma processing under a condition wherein a nitriding reaction or an oxidation reaction is mainly mediated through radical species of the nitrogen-containing plasma or the oxygen-containing plasma, respectively; and
a second step of performing a plasma processing under a condition wherein the nitriding reaction or an oxidation reaction is mainly mediated through ion species of the nitrogen-containing plasma or the oxygen-containing plasma, respectively.

13. The plasma processing method of claim 12, wherein the nitrogen-containing plasma or the oxygen-containing plasma is formed by introducing a microwave into the processing chamber with a planar antenna having a plurality of slots.

14. A plasma processing method for forming a nitride film or an oxide film, wherein a nitrogen-containing plasma or an oxygen-containing plasma is used to nitride or oxidize a surface of a target object in a processing chamber of the plasma processing apparatus, the plasma processing method comprising:
a first step of performing a plasma processing at a process pressure equal to or greater than 66.65 Pa and equal to or less than 1333 Pa; and
a second step of performing the plasma processing at a process pressure equal to or greater than 1.33 Pa and less than 66.65 Pa.

15. The plasma processing method of claim 14, wherein an electron temperature of the nitrogen-containing plasma or the oxygen-containing plasma is 0.7 eV or less in the first step; and the electron temperature of the nitrogen-containing plasma or the oxygen-containing plasma is 1.0 eV or greater in the second step.

16. The plasma processing method of any one of claims 1, 5, 12 and 14, wherein the target object is heated to a temperature of about 400˜800 °C.

17. The plasma processing method of claim 16, wherein the target object is heated to a temperature of about 600˜800 °C.
